(19) United States
(12) Patent Application Publication
(10) Pub. No.: US 2026/0279451 A1
(43) Pub. Date: Sep. 17, 2026

(54) MULTI-TIER NONVOLATILE MEMORY WITH FAILURE AND ERROR MITIGATION

(71) Applicant: Sandisk Technologies, Inc., Milpitas, CA (US)

(72) Inventors: Yuvaraj Krishnamoorthy, San Jose, CA (US); Jayavel Pachamuthu, San Jose, CA (US)

(73) Assignee: Sandisk Technologies, Inc., Milpitas, CA (US)

(21) Appl. No.: 19/075,844

(22) Filed: Mar. 11, 2025

(51) Int. Cl. G11C 16/10; G11C 16/08; G11C 16/32

(52) U.S. Cl. CPC G11C 16/102; G11C 16/08; G11C 16/32

(57) ABSTRACT

An apparatus includes one or more control circuits configured to connect to a plurality of nonvolatile memory cells in NAND strings that are coupled to word lines. The control circuits are configured to apply a first number of program pulses to a first set of word lines according to a first program scheme and apply a second number of program pulses to a second set of word lines according to a second program scheme. The second set of word lines includes one or more edge word line or joint word line and the second number of program pulses is greater than the first number of program pulses.

### BACKGROUND

The present technology relates to non-volatile memory and program operations for programming non-volatile memory cells.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise non-volatile memory or volatile memory. Non-volatile memory allows information to be stored and retained even when the non-volatile memory is not connected to a source of power (e.g., a battery).

A memory structure in the memory system typically contains many memory cells and various control lines. The memory structure may be three-dimensional. One type of three-dimensional structure has non-volatile memory cells arranged in vertical NAND strings. A NAND string contains memory cell transistors connected in series, a drain side select gate at one end, and a source side select gate at the other end. In some cases, a NAND memory is formed in two or more tiers with NAND strings extending through the tiers. The block typically has many word lines in each tier that provide voltages to the control gates of the memory cell transistors.

Non-volatile memory cells may be programmed to a number of data states to store data. Using a greater number of data states allows for more bits to be stored per memory cell. Some memory cells may be programmed to a data state by storing charge in the memory cell. For example, the threshold voltage (Vt) of a NAND memory cell can be set to a target Vt by programming charge into a charge storage region such as a charge trapping layer. The amount of charge stored in the charge trapping layer establishes the Vt of the memory cell. The cell may be read by detecting Vt.

Defects may occur in memory structures and may impact memory operations. Some defects may be detected during testing. Latent defects may not be detected during testing and may manifest at a later time (e.g., when a memory system is in use). For example, a block or portion of a block may become inaccessible (e.g., failure to program and/or read). In some cases, a high error rate may occur in data that is read from word lines of a block due to a latent defect. Mitigating failure and/or errors in nonvolatile memory may be challenging.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIG. 3 shows an example of a portion of a memory structure.

FIGS. 4A-F illustrate an example of a memory structure.

FIGS. 5A and 5B depict threshold voltage distributions.

FIG. 6 shows an example of applying read voltages to read memory cells.

FIG. 7 shows a portion of a 3D memory structure including a memory hole.

FIG. 8 shows an example of a memory structure having two tiers.

FIG. 9 shows an example of a two tier memory structure with misalignment.

FIGS. 10A-B show examples of NAND stings in two and three tier structures respectively.

FIGS. 11A-B show examples of programming using a first program scheme and a second program scheme respectively.

FIGS. 12A-B show examples of programming using a first program scheme and a second program scheme respectively.

FIG. 13 illustrates an example of a method that includes programming word lines with different program schemes.

FIG. 14 illustrates an example of a method that includes applying different program schemes to different sets of word lines.

### DETAILED DESCRIPTION

Technology is disclosed herein for mitigating failures and errors that may occur, for example, due to latent defects in multi-tier NAND memory structures. In some cases, certain word lines may be more prone to latent defects that may manifest after some use. For example, as the number of program erase cycles increases and wear occurs, latent defects may manifest. For example, voltages applied during program, read and/or erase operations may contribute to latent defects manifesting. Identifying word lines that are at risk may allow mitigating actions to be taken. For example, one or more word lines near a joint or interface between tiers of a multi-tier structure may be at high risk from effects of latent defects including failure (e.g., failure to read and/or program a block or portion of a block) and errors (e.g., a high error rate in data from some word lines of a block). In some cases, program operations directed to such high risk word lines may be adapted to mitigate problems associated with latent defects. For example, word lines at certain locations within a tier of a multi-tier structure may be more at risk than other word lines and a program scheme may be adapted to reduce risk of such defects manifesting (e.g., as failures and/or errors). While word lines at or near the middle of a tier may be programmed using a first program scheme, boundary word lines may be programmed using a second program scheme that uses more program pulses, which may be of lower voltage and/or shorter duration than the first program scheme. Boundary word lines may include joint word lines (e.g., one or more word line on either side of a joint between tiers) and/or edge word lines (e.g., one or more word lines at the lower edge of a block).

Aspects of the present technology are directed to technical problems associated with latent defects including read fail, write fail and/or high error rates. Aspects of the present technology provide technical solutions including using program schemes that are adapted to different word lines according to word line locations within respective tiers (e.g., using different program schemes for joint/edge word lines and for non-joint/edge word lines).

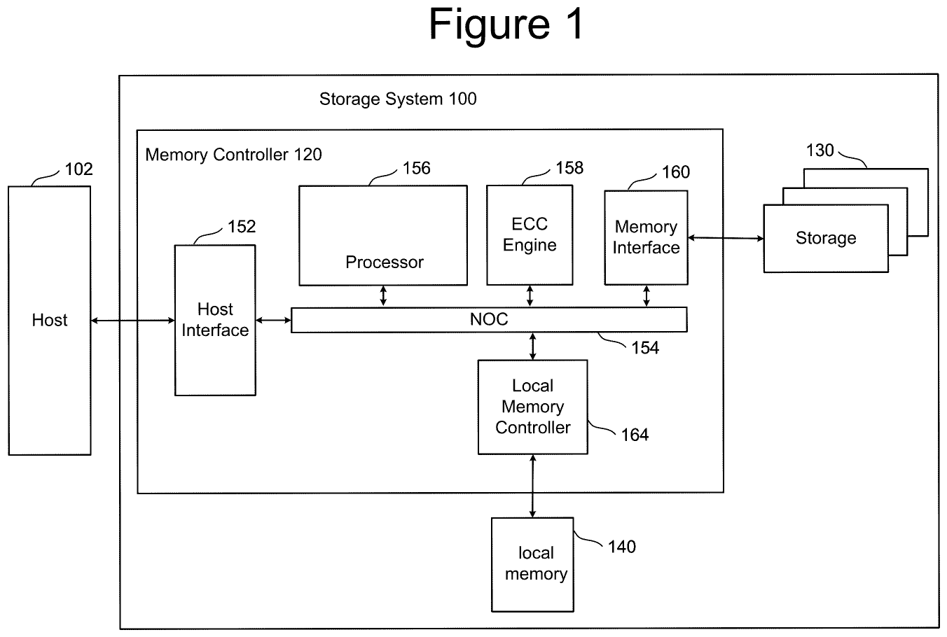

FIG. 1 is a block diagram of one embodiment of a storage system 100 that implements the technology described herein. In one embodiment, storage system 100 is a solid state drive (“SSD”). Storage system 100 can also be a memory card, USB drive or other type of storage system. The proposed technology is not limited to any one type of storage system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 (or storage controller) connected to non-volatile storage 130 and local high speed memory 140 (e.g., DRAM, SRAM, MRAM). Local memory 140 is non-transitory memory, which may include volatile memory or non-volatile memory. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus.

Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the non-volatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory die. One example implementation is to maintain tables (i.e. the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a storage 130 and a subset of the L2P tables are cached (L2P cache) in the local high speed memory 140.

Memory interface 160 communicates with non-volatile storage 130. In one embodiment, memory interface provides a Toggle Mode interface. Other interfaces can also be used. In some example implementations, memory interface 160 (or another portion of memory controller 120) implements a scheduler and buffer for transmitting data to and receiving data from one or more memory die.

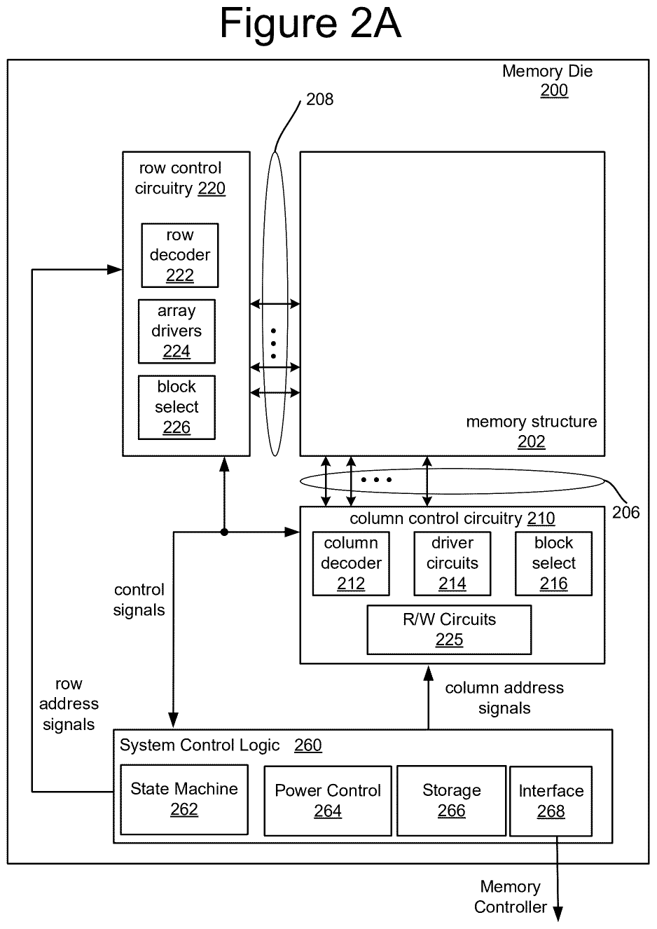

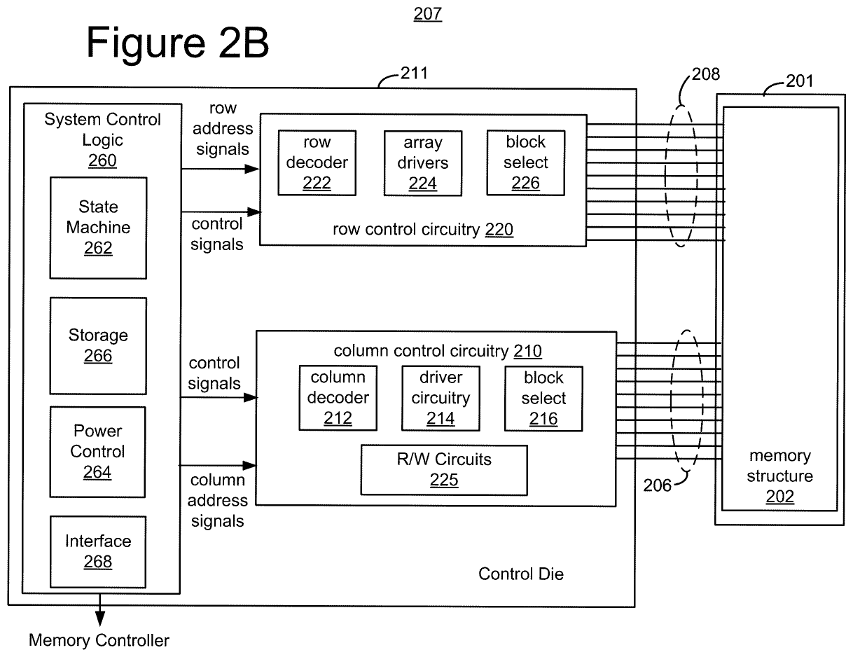

In one embodiment, non-volatile storage 130 comprises one or more memory dies. FIG. 2A is a functional block diagram of one embodiment of a memory die 200 that comprises non-volatile storage. Each of the one or more memory dies of non-volatile storage 130 can be implemented as memory die 200 of FIG. 2A. The components depicted in FIG. 2A are electrical circuits. Memory die 200 includes a memory structure 202 (e.g., memory array) that can comprise non-volatile memory cells (also referred to as non-volatile storage cells), as described in more detail below. The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic 260, and typically may include such circuits as row decoders 222, array drivers 224, and block select circuit 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. Although only a single block is shown for memory structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuit 216, as well as read/write circuitry, and I/O multiplexers.

System control logic 260 receives data and commands from memory controller 120 and provides output data and status to the host. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations. System control logic 260 includes storage 266 (e.g., RAM, registers, latches, etc.), which may be used to store parameters for operating the memory structure 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe-Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

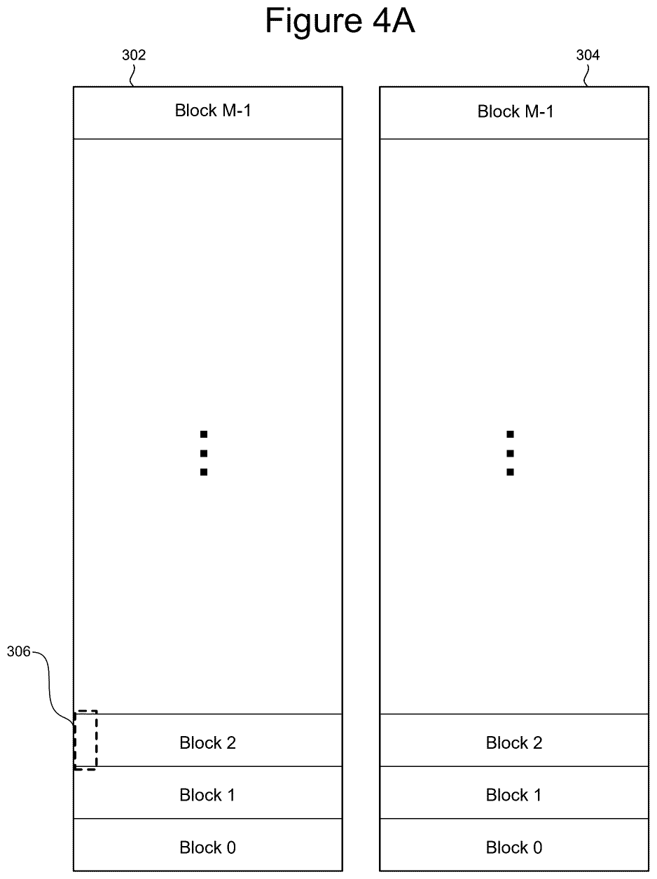

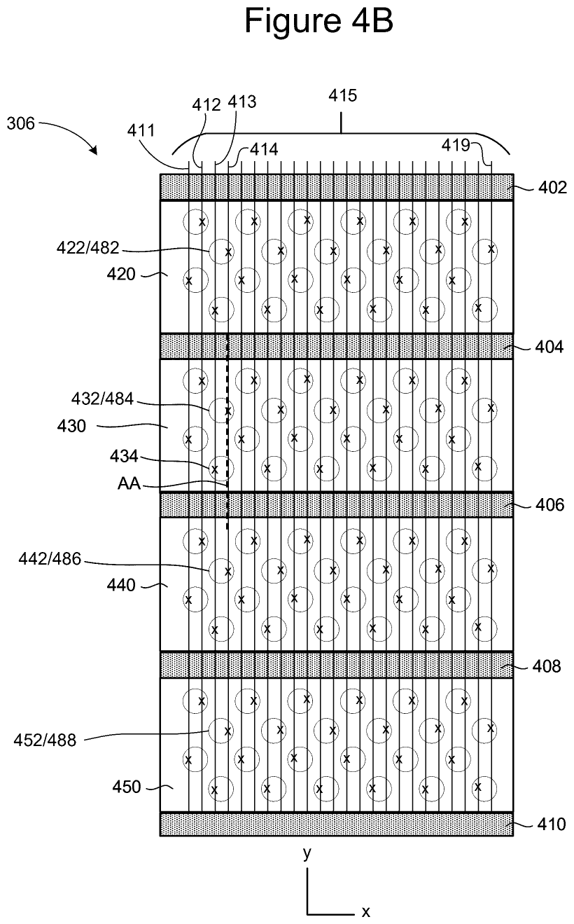

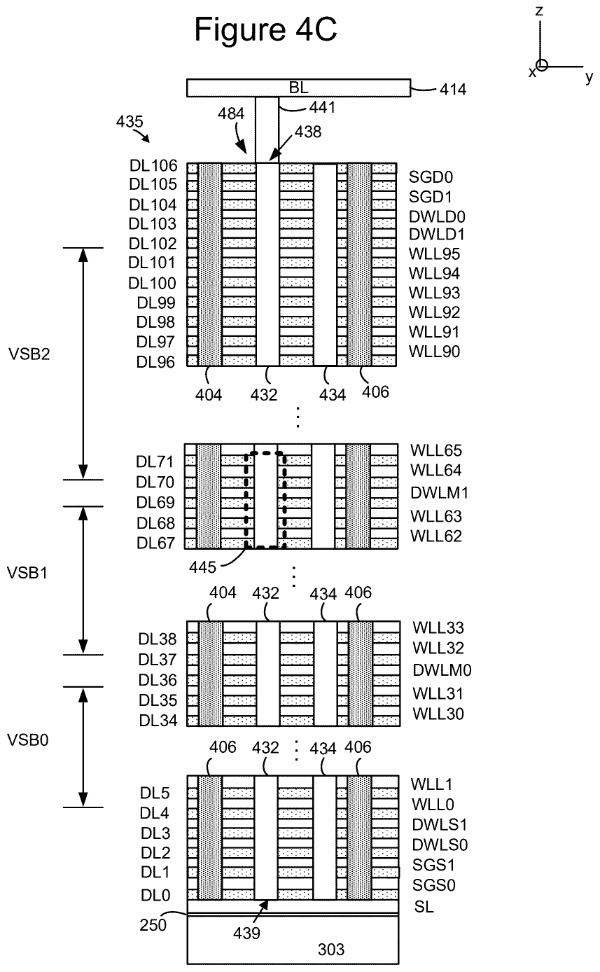

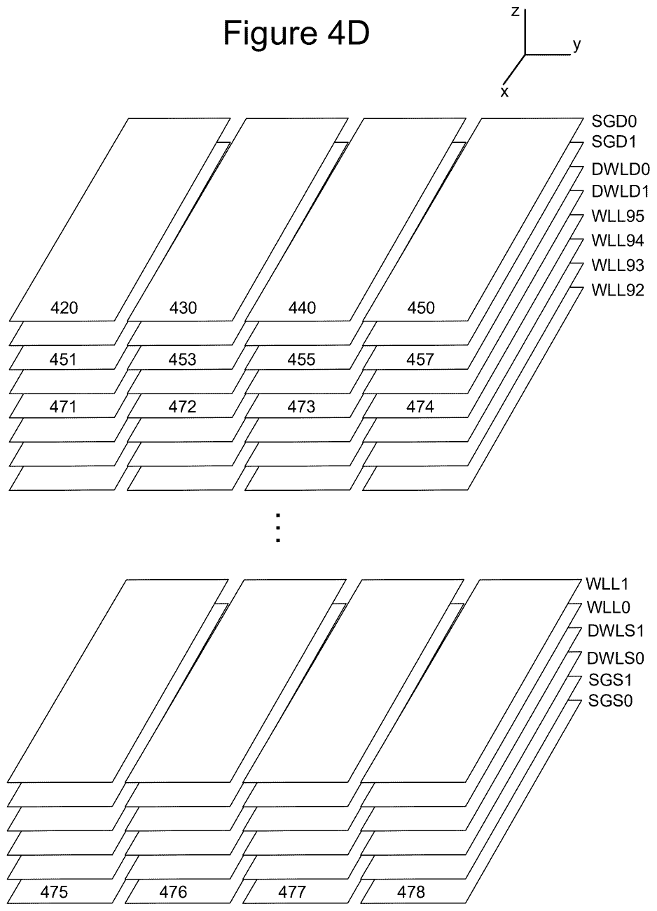

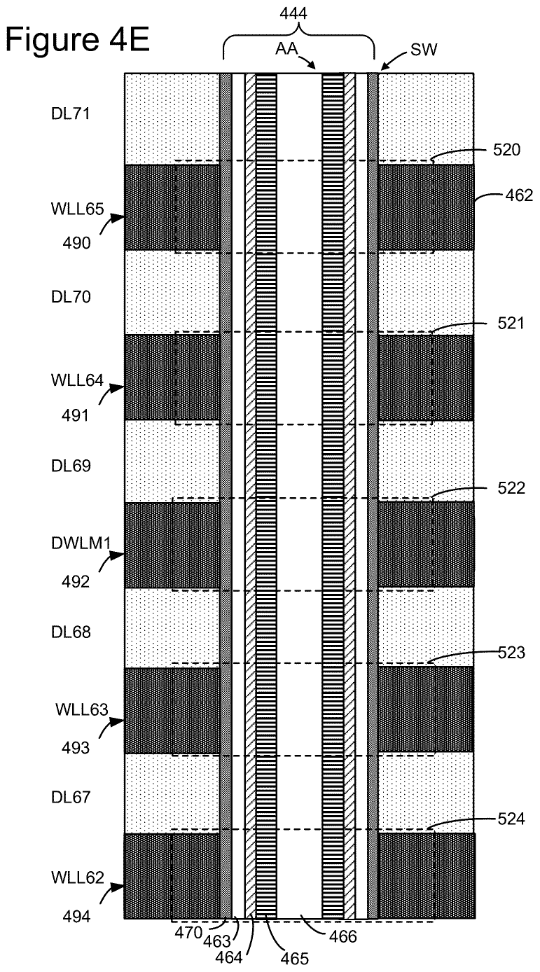

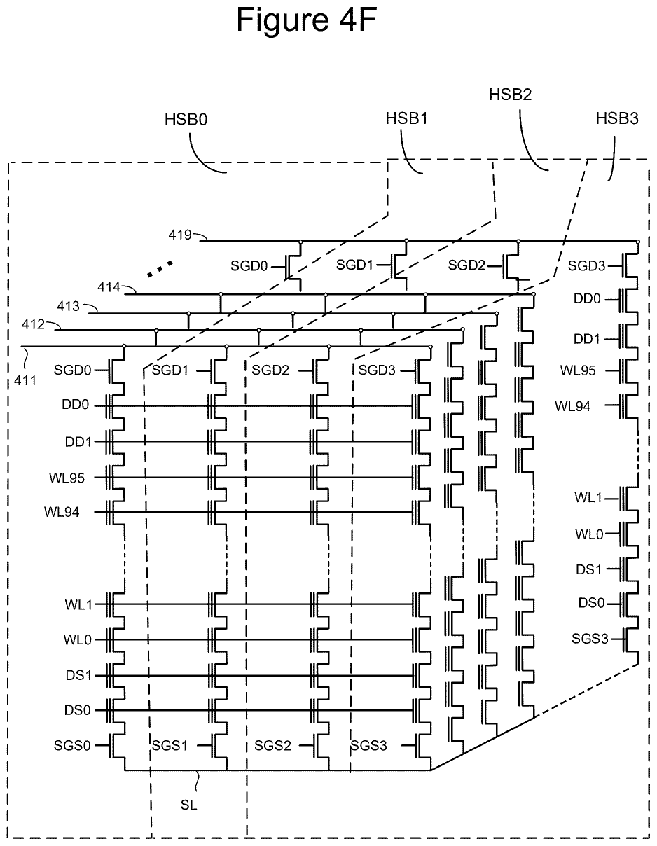

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures (see, for example, FIG. 4) in particular may benefit from specialized processing operations.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the non-volatile storage 130 of storage system 100. The integrated memory assembly 207 includes two types of semiconductor dies (or more succinctly, “die”). Memory structure die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2B shows an example of the peripheral circuitry, including control circuits, formed in a peripheral circuit or control die 211 coupled to memory structure 202 formed in memory structure die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate memory controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including read/write circuits 225 on the control die 211 coupled to memory structure 202 on the memory structure die 201 through electrical paths 206. For example, electrical paths 206 may provide electrical connection between column decoder 212, driver circuits 214, and block select circuit 216 and bit lines of memory structure 202. Electrical paths may extend from column control circuitry 210 in control die 211 through pads on control die 211 that are bonded to corresponding pads of the memory structure die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select circuit 226 are coupled to memory structure 202 through electrical paths 208. Each of electrical path 208 may correspond to a word line, dummy word line, or select gate line. Additional electrical paths may also be provided between control die 211 and memory structure die 201.

For purposes of this document, the phrases “a control circuit” or “one or more control circuits” can include any one of or any combination of memory controller 120, state machine 262, power control module 264, all or a portion of system control logic 260, all or a portion of row control circuitry 220, all or a portion of column control circuitry 210, read/write circuits 225, sense amps, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit.

For purposes of this document, the term “apparatus” can include, but is not limited to, one or more of, storage system 100, memory controller 120, storage 130, memory die 200, integrated memory assembly 207, and/or control die 211.

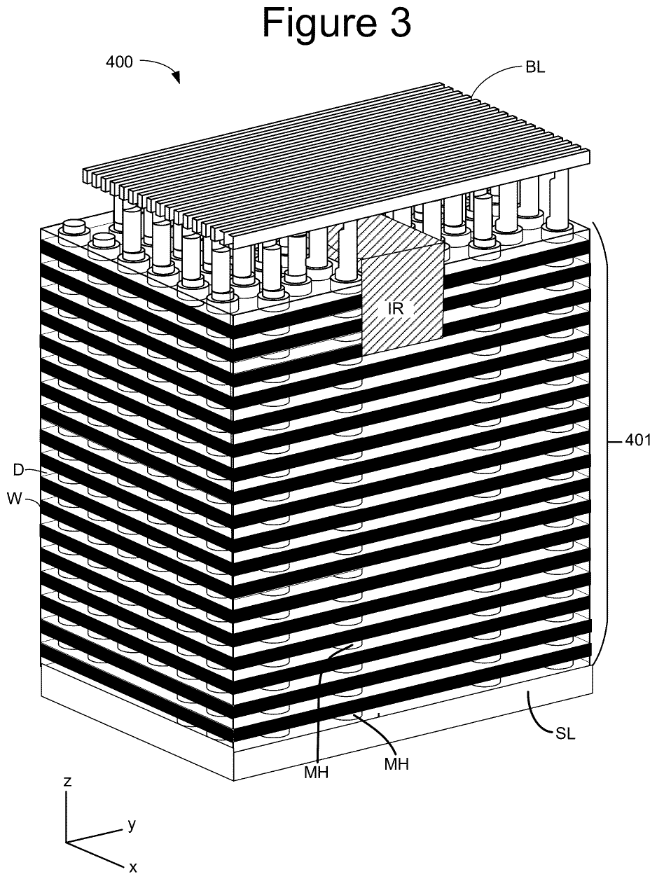

FIG. 3 is a perspective view of a portion of one example embodiment of a monolithic three dimensional memory array/structure that can comprise memory structure 202, which includes a plurality non-volatile memory cells arranged as vertical NAND strings. For example, FIG. 3 shows a portion 400 of one block of memory. The structure depicted includes a set of bit lines BL positioned above a stack 401 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements. In one embodiment the alternating dielectric layers and conductive layers are divided into four (or a different number of) regions (e.g., sub-blocks) by isolation regions IR. FIG. 3 shows one isolation region IR separating two sub-blocks. Below the alternating dielectric layers and word line layers is a source line layer SL. Memory holes are formed in the stack of alternating dielectric layers and conductive layers. For example, one of the memory holes is marked as MH. Note that in FIG. 3, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory structure 202 is provided below.

FIG. 4A is a block diagram explaining one example organization of memory structure 202, which is divided into two planes 302 and 304. Each plane is then divided into M blocks. In one example, each plane has about 2000 blocks. However, different numbers of blocks and planes can also be used. In one embodiment, a block of memory cells is a unit of erase. That is, all memory cells of a block are erased together. In other embodiments, memory cells can be grouped into blocks for other reasons, such as to organize the memory structure 202 to enable the signaling and selection circuits. In some embodiments, a block represents a groups of connected memory cells as the memory cells of a block share a common set of word lines.

FIGS. 4B-4F depict an example three dimensional (“3D”) NAND structure that corresponds to the structure of FIG. 3 and can be used to implement memory structure 202 of FIG. 2A or 2B. FIG. 4B is a block diagram depicting a top view of a portion of one block from memory structure 202. The portion of the block depicted in FIG. 4B corresponds to portion 306 in block 2 of FIG. 4A. In one embodiment, the memory array has many layers; however, FIG. 4B only shows the top layer.

FIG. 4B depicts a plurality of circles that represent the vertical columns. Each of the vertical columns include multiple select transistors (also referred to as a select gate or selection gate) and multiple memory cells. In one embodiment, each vertical column implements a NAND string. For example, FIG. 4B depicts vertical columns 422, 432, 442 and 452. Vertical column 422 implements NAND string 482. Vertical column 432 implements NAND string 484. Vertical column 442 implements NAND string 486. Vertical column 452 implements NAND string 488. More details of the vertical columns are provided below. Since the block depicted in FIG. 4B extends beyond the portion shown, the block includes more vertical columns than depicted in FIG. 4B.

FIG. 4B also depicts a set of bit lines 415, including bit lines 411, 412, 413, 414, . . . 419. FIG. 4B shows twenty-four bit lines because only a portion of the block is depicted. It is contemplated that more than twenty-four bit lines connected to vertical columns of the block. Each of the circles representing vertical columns has an “x” to indicate its connection to one bit line. For example, bit line 414 is connected to vertical columns 422, 432, 442 and 452.

The block depicted in FIG. 4B includes a set of local interconnects 402, 404, 406, 408 and 410 that connect the various layers to a source line below the vertical columns. Local interconnects 402, 404, 406, 408 and 410 also serve to divide each layer of the block into four regions; for example, the top layer depicted in FIG. 4B is divided into regions 420, 430, 440 and 450, which are referred to as fingers. In the layers of the block that implement memory cells, the four regions are referred to as word line fingers that are separated by the local interconnects. In one embodiment, the word line fingers on a common level of a block connect together to form a single word line. In another embodiment, the word line fingers on the same level are not connected together. In one example implementation, a bit line only connects to one vertical column in each of regions 420, 430, 440 and 450. In that implementation, each block has sixteen rows of active columns and each bit line connects to four rows in each block. In one embodiment, all of four rows connected to a common bit line are connected to the same word line (via different word line fingers on the same level that are connected together); therefore, the system uses the source side selection lines and the drain side selection lines to choose one (or another subset) of the four to be subjected to a memory operation (program, verify, read, and/or erase).

Although FIG. 4B shows each region having four rows of vertical columns, four regions and sixteen rows of vertical columns in a block, those exact numbers are an example implementation. Other embodiments may include more or less regions per block, more or less rows of vertical columns per region and more or less rows of vertical columns per block.

FIG. 4B also shows the vertical columns being staggered. In other embodiments, different patterns of staggering can be used. In some embodiments, the vertical columns are not staggered.

FIG. 4C depicts an embodiment of a stack 435 showing a cross-sectional view along line AA of FIG. 4B. Two SGD layers (SGD0, SDG1), two SGS layers (SGS0, SGS1) and six dummy word line layers DWLD0, DWLD1, DWLM1, DWLM0, DWLS0 and DWLS1 are provided, in addition to the data word line layers WLL0-WLL95. Each NAND string has a drain side select transistor at the SGD0 layer and a drain side select transistor at the SGD1 layer. In operation, the same voltage may be applied to each layer (SGD0, SGD1), such that the control terminal of each transistor receives the same voltage. Each NAND string has a source side select transistor at the SGS0 layer and a drain side select transistor at the SGS1 layer. In operation, the same voltage may be applied to each layer (SGS0, SGS1), such that the control terminal of each transistor receives the same voltage. Also depicted are dielectric layers DL0-DL106. More or less SGDs, SGSs and DWLs can be employed.

Columns 432, 434 of memory cells are depicted in the multi-layer stack. The stack includes a substrate 303, an insulating film 250 on the substrate, and a portion of a source line SL. A portion of the bit line 414 is also depicted. Note that NAND string 484 is connected to the bit line 414. NAND string 484 has a source-end 439 at a bottom of the stack and a drain-end 438 at a top of the stack. The source-end 439 is connected to the source line SL. A conductive via 441 connects the drain-end 438 of NAND string 484 to the bit line 414. The local interconnects 404 and 406 from FIG. 4B are also depicted.

The stack 435 is divided into three vertical sub-blocks (VSB0, VSB1, VSB2). Vertical sub-block VSB0 includes WLL0-WLL31. The following layers could also be considered to be a part of vertical sub-block VSB0 (SGS0, SGS1, DWLS0, DWLS1). Vertical sub-block VSB1 includes WLL32-WLL63. Vertical sub-block VSB2 includes WLL64-WLL95. The following layers could also be considered to be a part of vertical sub-block VSB2 (SGD0, SGD1, DWLD0, DWLD1). Each NAND string has a set of data memory cells in each of the vertical sub-blocks. Dummy word line layer DMLM0 is between vertical sub-block VSB0 and vertical sub-block VSB1. Dummy word line layer DMLM1 is between vertical sub-block VSB1 and vertical sub-block VSB2. The dummy word line layers have dummy memory cell transistors that may be used to electrically isolate a first set of memory cell transistors within the memory string (e.g., corresponding with vertical sub-block VSB0 word lines WLL0-WLL31) from a second set of memory cell transistors within the memory string (e.g., corresponding with the vertical sub-block VSB1 word lines WLL32-WLL63) during a memory operation (e.g., an erase operation or a programming operation).

FIG. 4D depicts an alternative view of the SG layers and word line layers of the stack 435 of FIG. 4C. The SGD layers SGD0 and SGD0 (the drain-side SG layers) each includes parallel rows of SG lines associated with the drain-side of a set of NAND strings. For example, SGD0 includes drain-side SG regions 420, 430, 440 and 450, consistent with FIG. 4B.

Below the SGD layers are the drain-side dummy word line layers. Each dummy word line layer represents a word line, in one approach, and is connected to a set of dummy memory cells at a given height in the stack. For example, DWLD0 comprises word line layer regions 451, 453, 455 and 457. A dummy memory cell, also referred to as a non-data memory cell, does not store data and is ineligible to store data, while a data memory cell is eligible to store data. Moreover, the Vth of a dummy memory cell is generally fixed at the time of manufacture or may be periodically adjusted, while the Vth of the data memory cells changes more frequently, e.g., during erase and programming operations of the data memory cells.

Below the dummy word line layers are the data word line layers. For example, WLL95 comprises word line layer regions 471, 472, 473 and 474.

Below the data word line layers are the source-side dummy word line layers.

Below the source-side dummy word line layers are the SGS layers. The SGS layers SGS0 and SGS1 (the source-side SG layers) each includes parallel rows of SG lines associated with the source-side of a set of NAND strings. For example, SGS0 includes source-side SG lines 475, 476, 477 and 478. Each SG line can be independently controlled, in one approach. Or the SG lines can be connected and commonly controlled.

FIG. 4E depicts a view of the region 445 of FIG. 4C. Data memory cell transistors 520 and 521 are above dummy memory cell transistor 522. Below dummy memory cell transistor 522 are data memory cell transistors 523 and 524. A number of layers can be deposited along the sidewall (SW) of the memory hole 444 and/or within each word line layer, e.g., using atomic layer deposition. For example, each column (e.g., the pillar which is formed by the materials within a memory hole) can include a blocking oxide/block high-k material 470, charge-trapping layer or film 463 such as SiN or other nitride, a tunneling layer 464, a polysilicon body or channel 465, and a dielectric core 466. A word line layer can include a conductive metal 462 such as Tungsten as a control gate. Alternately other metals can also be employed as control gate. For example, control gates 490, 491, 492, 493 and 494 are provided. In this example, all of the layers except the metal are provided in the memory hole. In other approaches, some of the layers can be in the control gate layer. Additional pillars are similarly formed in the different memory holes. A pillar can form a columnar active area (AA) of a NAND string.

When a data memory cell transistor is programmed, electrons are stored in a portion of the charge-trapping layer which is associated with the data memory cell transistor. These electrons are drawn into the charge-trapping layer from the channel, and through the tunneling layer. The Vth of a data memory cell transistor is increased in proportion to the amount of stored charge. During an erase operation, the electrons return to the channel.

Non-data transistors (e.g., select transistors, dummy memory cell transistors) may also include the charge trapping layer 463. In FIG. 4E, dummy memory cell transistor 522 includes the charge trapping layer 463. Thus, the threshold voltage of at least some non-data transistors may also be adjusted by storing or removing electrons from the charge trapping layer 463. It is not required that all non-data transistors have an adjustable Vth. For example, the charge trapping layer 463 is not required to be present in every select transistor.

Each of the memory holes can be filled with a plurality of annular layers comprising a blocking oxide layer, a charge trapping layer, a tunneling layer and a channel layer. A core region of each of the memory holes is filled with a body material, and the plurality of annular layers are between the core region and the WLLs in each of the memory holes.

In some cases, the tunneling layer 464 can comprise multiple layers such as in an oxide-nitride-oxide configuration.

FIG. 4F is a schematic diagram of a portion of the memory depicted in in FIGS. 3-4E. FIG. 4F shows physical word lines WLL0-WLL95 running across the entire block. The structure of FIG. 4F corresponds to portion 306 in Block 2 of FIGS. 4A-E, including bit lines 411, 412, 413, 414, . . . 419. Within the block, each bit line is connected to four NAND strings. Drain side selection lines SGD0, SGD1, SGD2 and SGD3 are used to determine which of the four NAND strings connect to the associated bit line(s). Source side selection lines SGS0, SGS1, SGS2 and SGS3 are used to determine which of the four NAND strings connect to the common source line. The block can also be thought of as divided into four horizontal sub-blocks HSB0, HSB1, HSB2 and HSB3. Horizontal sub-block HSB0 corresponds to those vertical NAND strings controlled by SGD0 and SGS0, Horizontal sub-block HSB1 corresponds to those vertical NAND strings controlled by SGD1 and SGS1, Horizontal sub-block HSB2 corresponds to those vertical NAND strings controlled by SGD2 and SGS2, and Horizontal sub-block HSB3 corresponds to those vertical NAND strings controlled by SGD3 and SGS3.

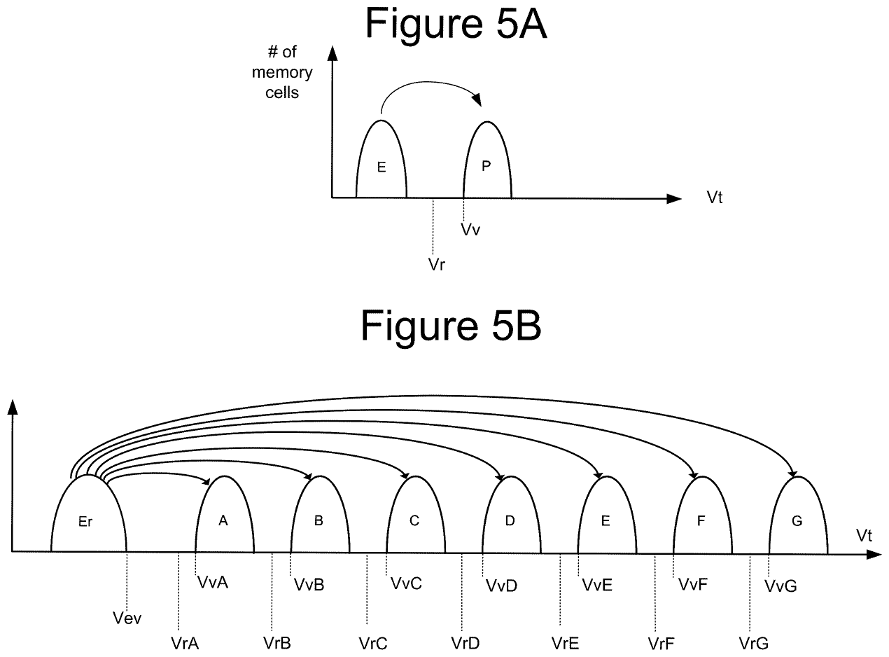

Memory cells in a memory system may be erased, programmed and read. At the end of a successful programming process, the threshold voltages of the memory cells should be within one or more distributions of threshold voltages for programmed memory cells or within a distribution of threshold voltages for erased memory cells, as appropriate. FIG. 5A is a graph of threshold voltage versus number of memory cells, which illustrates example threshold voltage distributions for the memory array when each memory cell stores one bit of data per memory cell. Memory cells that store one bit of data per memory cell data are referred to as single level cells (“SLC”). The data stored in SLC memory cells is referred to as SLC data; therefore, SLC data comprises one bit per memory cell. Data stored as one bit per memory cell is SLC data. FIG. 5A shows two threshold voltage distributions: E and P. Threshold voltage distribution E corresponds to an erased data state. Threshold voltage distribution P corresponds to a programmed data state. Memory cells that have threshold voltages in threshold voltage distribution E are, therefore, in the erased data state (e.g., they are erased). Memory cells that have threshold voltages in threshold voltage distribution P are, therefore, in the programmed data state (e.g., they are programmed). In one embodiment, erased memory cells store data “1” and programmed memory cells store data “0.” FIG. 5A depicts read reference voltage Vr. By testing (e.g., performing one or more sense operations) whether the threshold voltage of a given memory cell is above or below Vr, the system can determine whether a memory cells is erased (state E) or programmed (state P). FIG. 5A also depicts verify reference voltage Vv. In some embodiments, when programming memory cells to data state P, the system will test whether those memory cells have a threshold voltage greater than or equal to Vv in a program-verify (or “verify”) operation. In some embodiments, verify is not performed during SLC programming.

Memory cells that are configured to store multiple bit per memory cell data are referred to as multi-level cells (“MLC”). The data stored in MLC memory cells is referred to as MLC data; therefore, MLC data comprises multiple bits per memory cell. Data stored as multiple bits of data per memory cell is MLC data. In the example embodiment of FIG. 5B, each memory cell stores three bits of data. Other embodiments may use other data capacities per memory cell (e.g., such as two, four, or five bits of data per memory cell). Memory cells may be configured for SLC or MLC storage of data. In some cases, a block of nonvolatile memory cells may be configured for SLC data storage at one time and configured for MLC data storage at another time.

FIG. 5B shows eight threshold voltage distributions, corresponding to eight data states that store three bits per cell. The first threshold voltage distribution (data state) Er represents memory cells that are erased. The other seven threshold voltage distributions (data states) A-G represent memory cells that are programmed and, therefore, are also called programmed states. Each threshold voltage distribution (data state) corresponds to predetermined values for the set of data bits. The specific relationship between the data programmed into the memory cell and the threshold voltage levels of the cell depends upon the data encoding scheme adopted for the cells. In one embodiment, data values are assigned to the threshold voltage ranges using a Gray code assignment so that if the threshold voltage of a memory erroneously shifts to its neighboring physical state, only one bit will be affected. In an embodiment, the number of memory cells in each state is about the same.

FIG. 5B shows seven read reference voltages, VrA, VrB, VrC, VrD, VrE, VrF, and VrG for reading data from memory cells. By testing (e.g., performing sense operations) whether the threshold voltage of a given memory cell is above or below the seven read reference voltages, the system can determine what data state (i.e., A, B, C, D, . . . ) a memory cell is in. FIG. 5B also shows a number of verify reference voltages. The verify voltages are VvA, VvB, VvC, VvD, VvE, VvF, and VvG. In some embodiments, when programming memory cells to data state A, the system will test whether those memory cells have a threshold voltage greater than or equal to VvA. If the memory cell has a threshold voltage greater than or equal to VvA, then the memory cell is inhibited (locked out) from further programming. Similar reasoning applies to the other data states. In some embodiments, verify is not performed during MLC programming.

Each memory cell programmed according to the scheme illustrated in FIG. 5B, using 8 data states, may store 3 bits of data with each bit associated with a logical page. A read operation may be directed to one or more logical pages of data. Read operations directed to different logical pages may perform reads at different read voltages (e.g., it may not be necessary to perform read steps at all read voltages shown in response to a read request directed to only one or two of the logical pages stored).

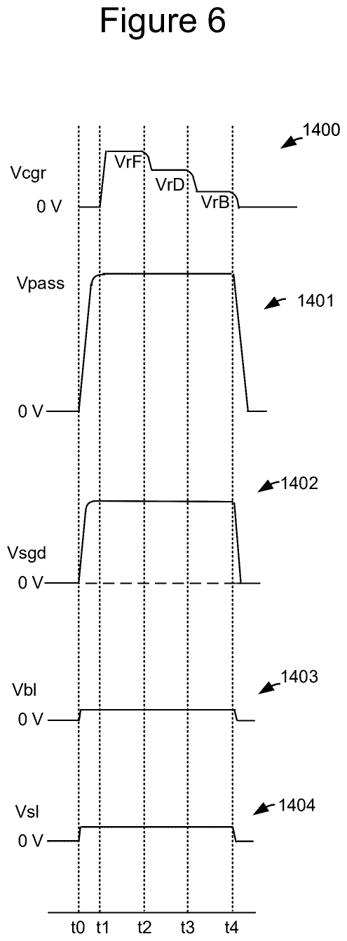

FIG. 6 illustrates example voltage signals (plots 1400-1404) for performing a read operation. The voltage 1400 depicts Vcgr, the voltage applied to control gates of the selected memory cells via the selected word line, WLn, to perform reads at three different read voltages (e.g., to obtain one logical page of data). The control gate read voltage, Vcgr (also referred to as a “read voltage”) is set to VrF, VrD and VrB. Sensing occurs during each value of Vcgr to determine the data of the logical page. Voltage 1401 denotes the read-pass voltage (Vpass) applied to the unselected word lines (e.g., WL0 to WLn-1 and WLn+1 to WL95). Vsgd denotes the SGD voltage 1402 and is set at a high level provided to selected SGD transistors (e.g., SGD0) in a conductive state. Vbl 1403 denotes the bit line voltage applied on bit lines such as bit lines 411 to 419 and is set at a level such as 0.5 V as part of the sensing process. Vsl 1404 denotes the source line voltage applied to SL and can be set at a small positive voltage, in one approach.

At time t0, unselected word line voltage 1401, Vsgd 1402, Vbl 1403 and Vsl 1404 are ramped up to respective target voltages. Subsequently, at time t1, the selected word line voltage, Vcgr 1400, is ramped up to a first read voltage VrF and a first read step is performed to identify which memory cells are on/off with VrF applied to their control gates. Subsequently, at time t2, the selected word line voltage, Vcgr 1400, is ramped down to a second read voltage, VrD, and a second read step is performed to identify which memory cells are on/off with VrD applied to their control gates. Subsequently, at time t3, the selected word line voltage, Vcgr 1400, is ramped down to a third read voltage, VrB, and a third read step is performed to identify which memory cells are on/off with VrB applied to their control gates. Subsequently, at time t4, the selected word line voltage, Vcgr 1400, is ramped down to a post-read voltage (e.g., 0 volts). While the example of FIG. 6 shows a sequence of three different read voltages to read one logical page, in other examples, other sequences with different numbers of read voltages may be used. Read operations such as the read operation illustrated in FIG. 6 may be affected by latent defects so that a read fail occurs or data is read with a higher error rate than desirable (e.g., requiring significant resources to decode).

While FIGS. 4A-F illustrate examples of a 3D NAND memory structure in a simplified manner, some memory structures may differ from the examples shown in ways that may affect memory operation (e.g., may affect operations including read operations such as illustrated in FIG. 6 and/or program operations as illustrated in FIGS. 5A-B). For example, while FIG. 4E shows memory hole 444 having a uniform diameter, in some cases memory hole diameter may include some nonuniformity, which may cause nonvolatile memory cells at different levels (e.g., along different word lines) to have different characteristics. In some cases, nonvolatile memory cells of certain word lines may be more prone to certain failure modes than nonvolatile memory cells of other word lines.

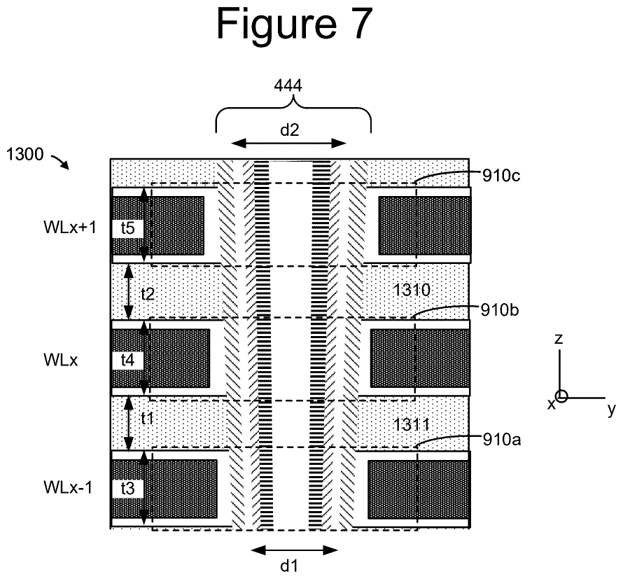

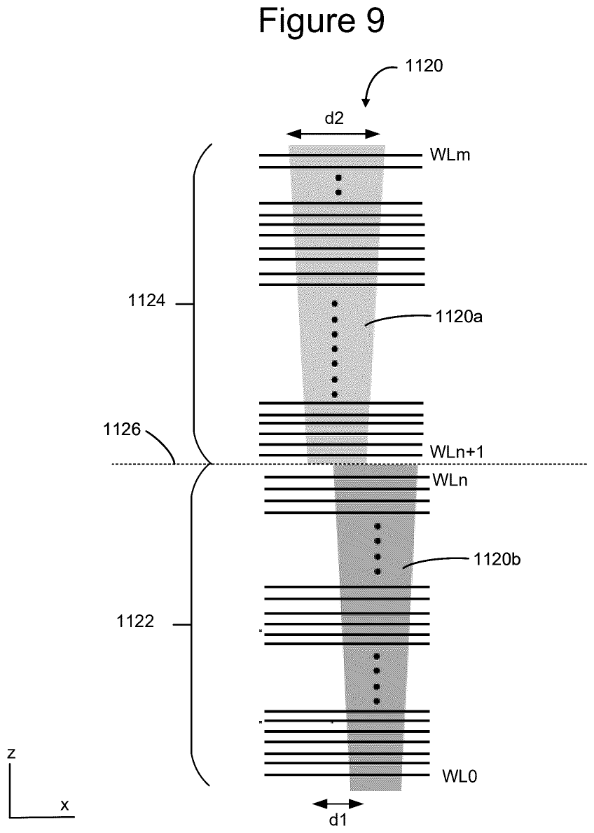

FIG. 7 shows a portion of memory hole 444 (as previously illustrated in FIG. 4E) which includes three memory cells, 910a-c, coupled to three word lines WLx−1 to WLx+1 respectively. FIG. 9 shows that the diameter of memory hole 444 is not uniform. For example, while memory hole has a first diameter, d1, at the lowest point shown (bottom of WLx−1) it has a second diameter, d2, at the highest point shown (top of WLx+1). Such a non-uniform shape may result from an etching process used to form a memory hole. Non-uniform memory hole diameter may result in non-uniform memory cell characteristics. Memory hole diameter may vary according to a pattern (e.g., increasing from bottom to top) which may allow measures to be taken to address different memory cell characteristics that may result (e.g., different characteristics at different levels). Other physical dimensions or material properties may vary from layer to layer in a 3D memory structure, which may cause non-uniformity between memory cells of different layers.

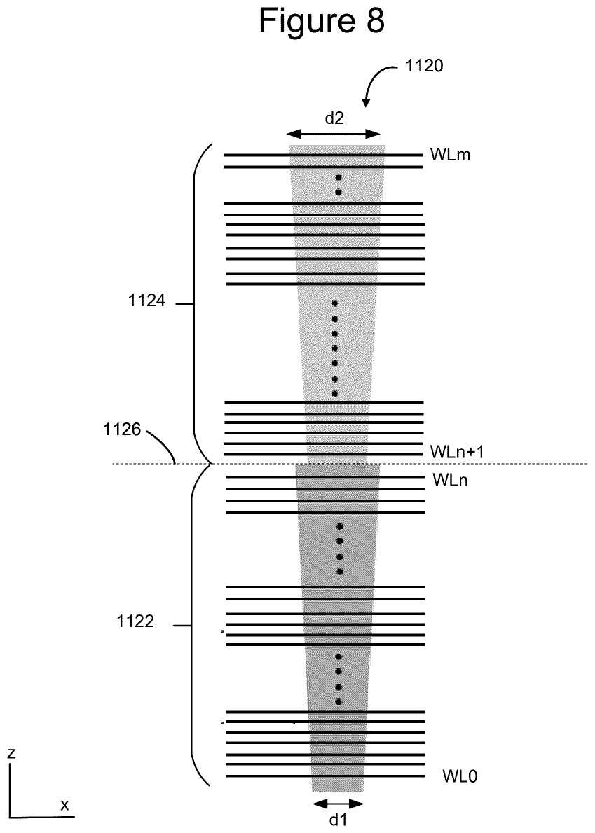

In some memory structures, memory holes are formed in multiple tiers so that tapering of memory holes with depth is not continuous (e.g., memory hole diameter may taper in each tier with a discontinuity at a joint between tiers). FIG. 8 shows an example of a 3D NAND memory structure that includes a memory hole 1120 formed in two tiers, lower tier 1122 and upper tier 1124, which are physically connected at a joint 1126 (interface). In each tier, memory hole 1120 tapers so that at the highest level shown (highest word line level WLm) the diameter of memory hole 1120, d2, is greater than the diameter, d1, at the lowest level shown (lowest word line WL0). This tapering is non-uniform with a discontinuity between WLn and WLn+1 where a tier interface along joint 1126 is located. For example, the diameter of memory hole 1120 at WLn may be d2 while the diameter at WLn+1 may be d1. In some cases, memory cells near the bottom of a memory hole may be prone to program and/or read failures. For example, memory cells near the bottom of lower tier 1122 (e.g. memory cells of one or more word lines including WL0) and near the bottom of upper tier 1124 (e.g., one or more word lines including WLn+1) may have increased risk of program and/or read failure due to latent defects or otherwise.

In some cases, some degree of misalignment may occur between tiers. For example, memory hole portions of each tier may be formed by a separate patterning and etching process, with the pattern for memory holes of a tier aligned with the pattern of the previous tier to enable memory hole continuity. However, alignment may be imperfect, which may affect memory hole structures and may cause defects including latent defects.

FIG. 9 shows an example of memory hole 1120, which includes an upper memory hole portion 1120a formed in upper tier 1124 and a lower memory hole portion 1120b formed in lower tier 1122. FIG. 9 shows misalignment of upper memory hole portion 1120a and lower memory hole portion 1120b, which may affect characteristics of the memory structure. For example, word lines in one or more layers near joint 1126 between upper tier 1124 and lower tier 1122 may be affected by such misalignment (e.g., short circuit or high leakage between word lines and/or between memory holes and word lines). Such word lines may be prone to program and/or read failures. For example, memory cells of one or more joint word line on either side of an interface between tiers (e.g., memory cells of word lines including WLn and WLn+1) may have increased risk of program and/or read failure.

In some cases, defects may be detected during testing and memory dies (or portions thereof) may be designated as failed and may be discarded (e.g., not used to store user data). In some cases, defects may be latent so that memory cells pass testing and may be used to store user data. Subsequently, such defects may manifest, which may cause data to be unreadable or readable with a high error rate. While correction of high error rate data may be possible (e.g., Error Correction Code (ECC), Exclusive OR (XOR) and/or other redundancy may allow recovery of data that is unreadable or readable with a high error rate). However, such recovery may require significant time and/or resources and it may be preferable to maintain user data in a lower error rate condition (e.g., a condition that does not require significant time and resources to read and send to a host).

Aspects of the present technology are directed to technical problems associated with read fail, program fail, high error rate and/or other problems which may manifest along certain word lines of a 3D NAND memory (e.g., due to latent defects). Aspects of the present technology provide technical solutions to problems associated with certain word lines including selectively applying proactive measures to mitigate or eliminate such problems.

Memory cells of word lines that are at or near boundaries of a tier may be at risk of latent defects. Boundary word lines may include word lines close to joints between tiers (“joint word lines”) such as WLn and WLn+1, which are adjacent to joint 1126. For example, WLn may be the uppermost word line of tier 1122 while WLn+1 may be the lowest word line of tier 1124. In some cases, two or more word lines on either side of a joint may be considered joint word lines. Boundary word lines may also include word lines that are not near a joint, which are at the edge of a tier (“edge word lines”) such as WL0 of FIG. 9. Memory cells of joint word lines and edge word lines are examples of memory cells that may be subject to proactive measures while memory cells of other word lines (e.g., non-joint/edge or middle word lines) may not be subject to the proactive measures (e.g., proactive measures are selectively applied to certain word lines that are identified as being at high risk because of their proximity to a tier boundary such as a joint between tiers or an edge of a tier).

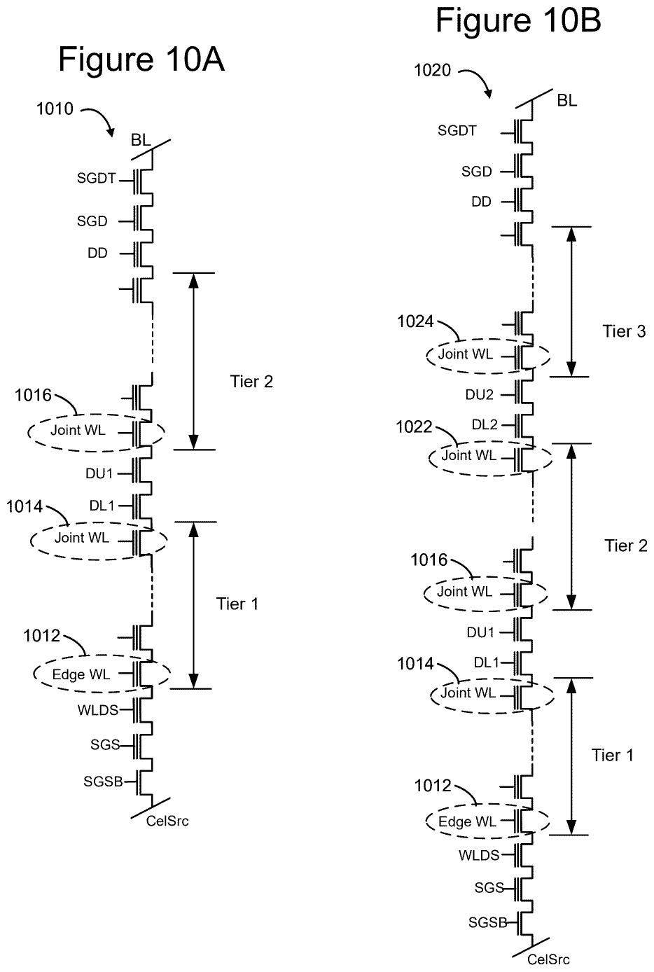

FIG. 10A illustrates an example of a NAND string 1010 in a two-tier memory structure. NAND string 1010 is connected to a common source (CelSrc) at the bottom via source select gates SGS and SGSB and a source-side dummy word line WLDS. A lower tier, tier 1, includes word lines including an edge word line 1012 and a joint word line 1014. Edge word line 1012 may be the lowermost data word line of tier 1 (e.g., WLDS may be a dummy word line that does not store data). Joint word line 1014 may be the uppermost data word line of tier 1 (e.g., DL1 may be a dummy word line that does not store data). An upper tier, tier 2, includes word lines including joint word line 1016 (e.g., lowermost data word line of tier 2). When accessing memory cells of edge word line 1012 and joint word lines 1014 and 1016 preemptive measures may be used to reduce risk (e.g., risk of latent defects manifesting).

FIG. 10B illustrates an example of a NAND string 1020 in a three-tier memory structure. NAND string 1020 includes edge word line 1012 and joint word lines 1014 and 1016 as in FIG. 10A. In addition, NAND string 1020 includes joint word lines 1022 and 1024 on either side of an interface between tier 2 (middle tier in this example) and tier 3 (upper tier). When accessing memory cells of edge word line 1012 and joint word lines 1014, 1016, 1022 and 1024 preemptive measures may be used to reduce risk of errors. While the examples of FIGS. 10A-B show two and three tier examples respectively, aspects of the present technology are not limited to the examples shown and may be extended to any number of tiers.

Preemptive measures may be taken to reduce the risk of failure of memory cells of certain word lines that are identified as high-risk word lines (e.g., boundary word lines including joint and/or edge word lines). Such measures may include schemes for one or more of read, write and/or erase that may reduce risk (e.g., compared with schemes used for other word lines that are not identified as high-risk such as middle word lines).

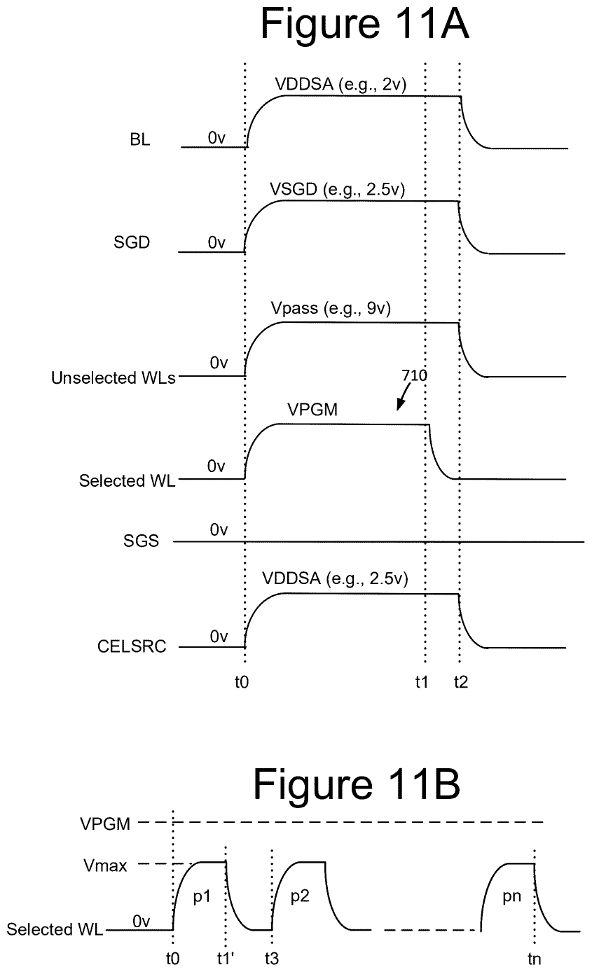

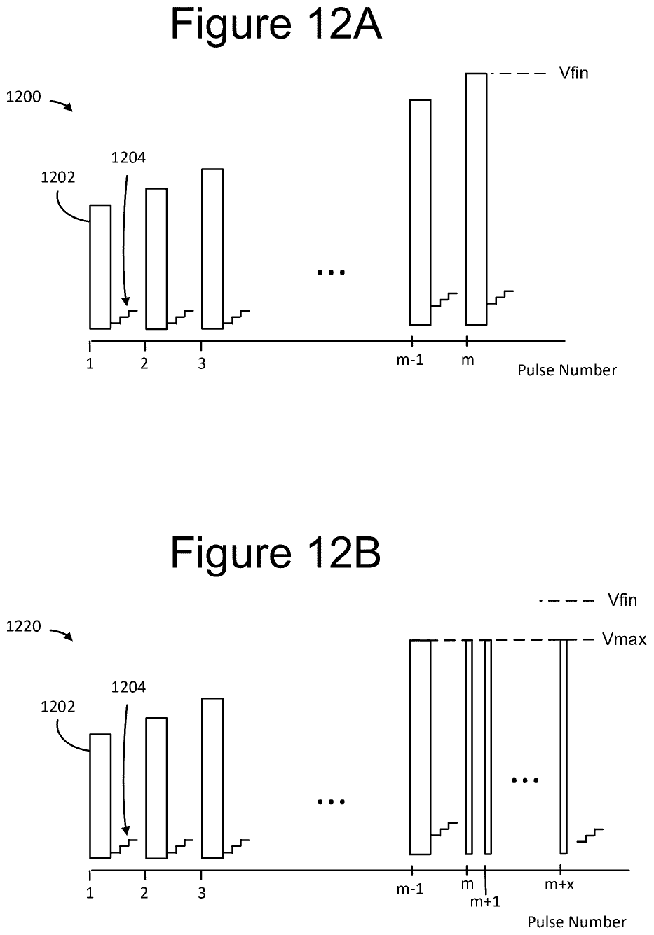

In some cases, program pulses may subject a memory cell to significant stress, which may cause a latent defect to manifest. Reducing such stress may reduce or delay manifestation of latent defects and associated consequences (failure or high error rate). FIGS. 11A-12D illustrate examples of schemes including reduced-risk write schemes that may be used when programming memory cells of word lines that are identified as high-risk. FIG. 11A shows an example of applying a single programming pulse 710 to program memory cells that use two data states to store one bit of data per cell (e.g., as previously illustrated in FIG. 5A). In this example, no verification may be necessary so that one pulse step and zero verification steps (1P0V) is sufficient to program cells. Such a write scheme may be used to program SLC memory cells of NAND strings of a memory array.

The horizontal axis of FIG. 11A represents time with each trace labeled according to the component on which the corresponding voltage is applied (voltage increasing in the vertical direction). At time t0, voltages are ramped up from 0 volts to various target voltages. For example, bit line (“BL”) voltage ramps up from 0 volts to VDDSA (e.g., 2V). Select Gate Drain (“SGD”) voltage ramps up from 0 volts to VSGD (e.g., 2.5V) to turn SGD transistors on (conductive). Unselected word lines (“WLs”) voltages ramp up from 0 volts to a pass voltage, Vpass (e.g., 9V), to make corresponding channels conductive. Selected WL voltage ramps up from 0 volts to a program voltage, VPGM for a single pulse 710 to cause programming. Select Gate Source (“SGS”) voltage is maintained at 0 volts to maintain SGS transistors off (nonconductive). Source voltage (“CELSRC”) ramps up from 0 volts to VDDSA (e.g., 2.5 volts).

Subsequently, at time t1, the selected WL voltage ramps down from VPGM at the end of program pulse 710, while other voltages remain at their previous levels. Subsequently, at time t2, other voltages including BL, SGD, unselected WL and CELSRC voltages ramp down.

Pulse 710 illustrated in FIG. 11A may cause significant stress on memory cells including high-risk memory cells. In some cases, risk may be reduced by avoiding the program scheme of FIG. 11A when programming high-risk memory cells and using an alternative program scheme.

FIG. 11B illustrates an example of a reduced-risk scheme that may be applied when programming memory cells of high-risk word lines (e.g., edge and/or joint word lines). For example, when a high-risk word line is selected, the selected word line may receive the voltage signal shown in FIG. 11B (other components may receive the same voltages as shown in FIG. 11A). In contrast non-high-risk word lines may receive the selected word line signal (pulse 710) illustrated in FIG. 11A.

FIG. 11B shows n program pulses, numbered p1 to pn, that may be used to program memory cells along the selected word line. In the example illustrated, all pulses have the same pulse height or program voltage, Vmax, which may be the same as the single-pulse voltage of FIG. 11A or may be different (e.g., lower than VPGM as shown in FIG. 12B). In other examples, pulses may have different pulse heights (e.g., nonuniform from pulse to pulse). At time t0, the first pulse, p1, is initiated and at time t1′ the pulse is terminated. The pulse width (time from t0 to t1′) may be significantly less than the pulse width of FIG. 11A (time from t0 to t1). Subsequently, at time t3, a second pulse, p2, is initiated. Second pulse, p2, and subsequent pulses may be identical to first pulse, p1, or different. A sequence of n pulses continues until the end of final pulse, pn, at time tn. The number n may be any number greater than one, for example, two, three, four, five or more. While each individual pulse p1 to pn may be narrower than the voltage pulse 710, the combined width all pulses p1 to pn (time from t0 to tn) may be longer than for pulse 710 (more than time from t0 to t1). By applying the scheme of FIG. 11B selectively (e.g., only on high-risk word lines) the increased time may be maintained at an acceptable level.

FIG. 12A-B show aspects of the present technology implemented in MLC memory (e.g., storing more than one bit per memory cell using more than two data states as illustrated in FIG. 5B).

FIG. 12A depicts a voltage signal that includes a plurality of pulses applied to control gates of nonvolatile memory cells (e.g., applied to a selected word line) in an example program operation. The horizontal axis denotes a pulse number, ranging from 1 to m, and the vertical axis denotes program voltage. Voltages applied on other memory structure components (e.g., bit lines, select lines, unselected word lines) may be similar to those shown in FIG. 11A. During a program operation, program loops are performed for a selected word line in a selected block in each plane. A program loop comprises a program portion in which a program pulse at a corresponding program voltage is applied to the selected word line followed by a verify portion in which a verify signal is applied to the selected word line while one or more verify tests are performed for the associated memory cells. Other than the erased state, each assigned state has a verify voltage which is used in the verify test for the state in a program operation.

The voltage signal 1200 includes a series of program pulses at different program voltages, including an initial program pulse 1202, which are applied to a word line selected for programming. In this example, the voltage signal includes program pulses having corresponding program voltages which increase stepwise in amplitude up to a final program voltage Vfin applied in pulse m. This may be referred to as incremental step pulse programming, where the program voltage starts with an initial program pulse 1202 at an initial level and increases in a step in each successive program loop, for instance, until the program operation is completed. A successful completion occurs when the threshold voltages of the selected memory cells reach the verify voltages of the assigned data states.

A program operation can include a single programming pass (e.g., as in FIG. 11A) or multiple programming passes (e.g., as in FIG. 12A), where each pass uses incremental step pulse programming, for instance. In SLC memory, where two data states are used, verify may be unnecessary.

The verify signal in each program loop of a multi-pulse scheme, including example verify signal 1204, can include one or more verify voltages, based on the assigned data states which are being verified for the program loop. The verify tests can encompass lower assigned data states and then midrange assigned data states and then higher assigned data states as the program operations proceeds. The example verify signals depict three verify voltages as a simplification.

The data which is programmed or read can be arranged in pages. For example, with four data states, or two bits per cell, two logical pages of data can be stored together in a page. An example encoding of bits for the Er, A, B and C states is 11, 10, 00 and 01, respectively, in the format of upper page (UP) bit/lower page (LP) bit. A lower page read may use VrA and VrC and an upper page read may use VrB. With eight data states, or three bits per cell, three pages of data can be stored. An example encoding of bits for the Er, A, B, C, D, E, F and G states is 111, 110, 100, 000, 010, 011, 001 and 101, respectively.

In some cases, a scheme such as shown in FIG. 12A may be used to program memory cells of a first set of word lines of a memory structure (e.g., middle word lines that are not near boundaries of a tier) while a different scheme is used to program memory cells of a second set of word lines of the same memory structure (e.g., high-risk word lines, which may include edge word lines and/or joint word lines).

FIG. 12B shows an example of a voltage signal 1220, which includes a series of voltage pulses used to program memory cells of word lines of a second set of word lines (e.g., a set of word lines identified as high risk such as edge and/or joint word lines). Pulses 1 to m−1 may be identical to FIG. 12A. However, in contrast with FIG. 12A, subsequent to pulse m−1 a series of pulses (numbered m to m+x) are applied, which have a voltage, Vmax, which is less than that of pulse m, Vfin (lower pulse height). This may result in less stress on memory cells. Pulses m to m+x may also be of shorter duration than pulses 1 to m−1 (and pulse m of FIG. 12A). While FIG. 12B shows Vmax as equal to the voltage of pulse m−1, in other examples this is not the case (e.g., Vmax may be greater or less than the voltage of pulse m−1). The total time for programming may be increased (e.g., pulses m to m+x in FIG. 12B may take longer than pulse m of FIG. 12A). However, because this programming scheme is applied selectively, overall programming time may not be significantly affected.

While FIG. 12B corresponds to replacing pulse m of FIG. 12A with a series of x pulses of smaller pulse height and pulse width, in other examples more than one pulse may be replaced by such smaller pulses. For example, two or more pulses of FIG. 12A (e.g., pulses m and m−1 or pulses m to m-y where y may be any number less than m) may be replaced by smaller pulses.

Aspects of the present technology may include applying different program schemes to different word lines (e.g., applying different numbers of programming pulses and/or pulses of different pulse height and/or pulse width) according to the respective locations of word lines in a tier. For example, applying a first number of program pulses (e.g., one as in FIG. 11A or m as in FIG. 12A) to program nonvolatile memory cells of a first set of word lines to a target data state and applying a second number of program pulses (e.g., a number greater than the first number such as n as in FIG. 11B or m+x as in 12B) to program nonvolatile memory cells of a second set of word lines. The second set of word lines may be selected according to their locations in their respective tiers. For example, the second set of word lines may include an edge word line (word line(s) at or near the bottom of the lowest tier) and/or joint word line(s) (word lines at or near joints between tiers, e.g., at the top or bottom of a respective tier).

In the examples of FIGS. 11A-12B two different program schemes are used depending on word line location in a respective tier (e.g., a first program scheme for middle word lines and a second program scheme for edge and joint word lines). In other examples, more than two program schemes may be used. For example, joint word lines may be programmed using one program scheme while edge word lines may be programmed using a different program scheme (e.g., in addition to a program scheme used for non-edge/joint or middle word lines). Other location dependent schemes may also be applied.

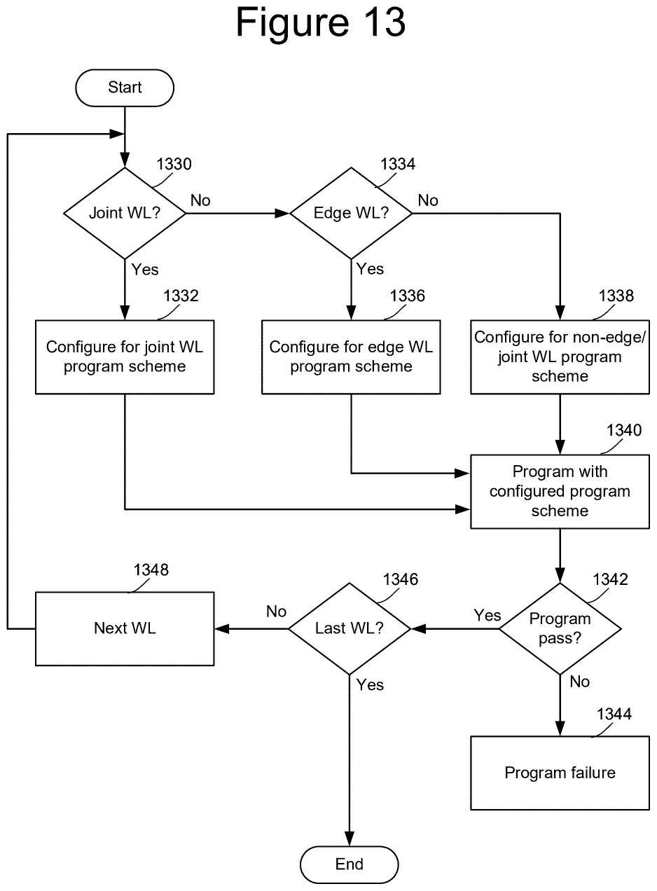

FIG. 13 illustrates an example of a method of programming memory cells of multiple word lines (e.g., word lines in two or more tiers of a NAND flash memory structure). The method includes making a determination 1330 as to whether the current word line is a joint word line (e.g., at or near a joint or interface between tiers) and, if it is, configuring for use of a joint word line program scheme 1332 (e.g., using an increased number of pulses of lower voltage and/or duration). If the current word line is not a joint word line then a determination 1334 is made as to whether the current word line is an edge word line (e.g., at or near the bottom of the lowest tier) and, if it is, configuring for use of an edge word line program scheme 1336. If the word line is neither a joint word line nor an edge word line then the method includes configuring for non-edge/joint word line (middle word line) program scheme (e.g., first program scheme of FIG. 11A or 12A). Configuring of steps 1332, 1334 and 1338 may include loading appropriate parameters into appropriate registers (e.g., set features register). The method includes programming with the configured program scheme 1340 (e.g., the joint word line program scheme, edge word line program scheme or non-edge/joint word line scheme) and determining if programming pass occurs 1342. If programming does not result in a program pass then a program failure routine 1344 is applied. If programming results in a program pass then a determination 1346 is made as to whether the current word line is the last word line (e.g., the last word line to be written in the current write command). If it is the last word line then the operation ends. If the current word line is not the last word line then the next word line becomes the current word line 1348 and the steps are repeated for the next word line (new current word line). This may continue until the last word line is reached.

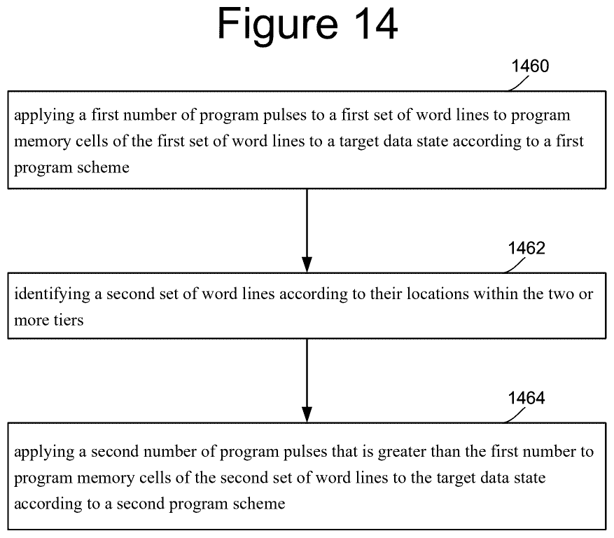

FIG. 14 illustrates an example of a method of programming nonvolatile memory cells in a multi-tier NAND memory structure (e.g., a structure that includes NAND strings extending through two or more tiers with word lines of the two or more tiers coupled to the memory cells). The method includes applying a first number of program pulses to a first set of word lines to program memory cells of the first set of word lines to a target data state according to a first program scheme 1460 (e.g., using a program scheme as illustrated in FIG. 11A or 12A to program non-edge/joint word lines). The method further includes identifying a second set of word lines according to their locations within the two or more tiers 1462 (e.g., identifying edge and/or joint word lines) and applying a second number of program pulses that is greater than the first number to program memory cells of the second set of word lines to the target data state according to a second program scheme 1464. For example, applying n program pulses instead of one pulse as shown in FIG. 11B or applying m+x pulses instead of m pulses as shown in FIG. 12B. The program pulses of the second program scheme may have a lower voltage and/or pulse width compared to the program pulses of the first program scheme.

The methods illustrated by FIGS. 13 and 14 may be implemented using any suitable circuits. For example, control circuits such as row control circuitry 220 configured as described above (e.g., in combination with system control logic 260 and/or other circuits) may be used to selectively apply different program schemes according to word line location in a respective tier. Such control circuits (e.g., row control circuitry 220 alone and/or in combination with system control logic 260 and/or other circuits) may be considered as an example of means for selecting a program scheme for a word line according to word line location in a respective tier, applying a first number of program pulses to program nonvolatile memory cells of a first set of word lines located in the middle of respective tiers to a target data state according to a first program scheme, applying a second number of program pulses that is greater than the first number to program nonvolatile memory cells of a second set of word lines located at edges of respective tiers to the target data state according to a second program scheme.

According to examples of the present technology, an apparatus includes one or more control circuits configured to connect to a plurality of nonvolatile memory cells in NAND strings that are coupled to word lines. The control circuits are configured to apply a first number of program pulses to a first set of word lines according to a first program scheme, apply a second number of program pulses to a second set of word lines according to a second program scheme. The second set of word lines includes one or more edge word line or joint word line and the second number of program pulses is greater than the first number of program pulses.

In one or more embodiments, the first number is one and the second number is two or more.

In one or more embodiments, the first number is more than one and the second number is more than the first number by at least two.

In one or more embodiments, the NAND strings are formed in a lower tier and an upper tier that are joined along an interface, the second set of word lines consists of an edge word line at the bottom of the lower tier, a first joint word line at the top of the lower tier and a second joint word line at the bottom of the upper tier.

In one or more embodiments, the first set of word lines consists of all word lines coupled to the NAND strings except the edge word line, the first joint word line and the second joint word line.

In one or more embodiments, the NAND strings are formed in a lower tier, a middle tier and an upper tier, the lower tier is joined to the middle tier along a first interface and the upper tier joined to the middle tier along a second interface, the second set of word lines consists of an edge word line at the bottom of the lower tier, a first joint word line at the top of the lower tier, a second joint word line at the bottom of the middle tier, a third joint word line at the top of the middle tier and a fourth joint word line at the bottom of the upper tier.

In one or more embodiments, the first set of word lines consists of all word lines coupled to the NAND strings except the edge word line and the first, second, third and fourth joint word lines.

In one or more embodiments, the program pulses of the first program scheme have a first voltage, the program pulses of the second program scheme have a second voltage and the second voltage is less than the first voltage.

In one or more embodiments, the first program scheme includes applying the first number of program pulses over a first time period and the second program scheme includes applying the second number of program pulses over a second time period that is longer than the first time period.

An example method of programming a plurality of nonvolatile memory cells in a memory structure that includes NAND strings extending through two or more tiers with word lines of the two or more tiers coupled to the plurality of nonvolatile memory cells includes: applying a first number of program pulses to a first set of word lines to program memory cells of the first set of word lines to a target data state according to a first program scheme; identifying a second set of word lines according to their locations within the two or more tiers; and applying a second number of program pulses that is greater than the first number to program memory cells of the second set of word lines to the target data state according to a second program scheme.

In one or more embodiments, applying the first number of program pulses consists of applying a single pulse and applying the second number of program pulses consists of applying two or more pulses.

In one or more embodiments, applying the first number of pulses consists of applying two or more pulses and applying the second number of pulses consists of applying more than the first number of pulses.

In one or more embodiments, identifying the second set of word lines includes identifying at least one edge word line at the bottom of a lowest tier of the two or more tiers.

In one or more embodiments, identifying the second set of word lines further includes identifying at least one joint word line at the top of the lowest tier of the two or more tiers.

In one or more embodiments, identifying the second set of word lines further includes identifying at least one joint word line at the bottom of a tier above the lowest tier of the two or more tiers.

In one or more embodiments, the program pulses of the first program scheme have a first voltage, the program pulses of the second program scheme have a second voltage and the second voltage is less than the first voltage.

In one or more embodiments, the program pulses of the first program scheme have a first pulse width, the program pulses of the second program scheme have a second pulse width and the second pulse width is less than the first pulse width.

An example storage system includes a plurality of nonvolatile memory cells arranged in NAND strings that extend through two or more tiers and connect to word lines in each tier; and means for selecting a program scheme for a word line according to word line location in a respective tier of the two or more tiers, applying a first number of program pulses to program nonvolatile memory cells of a first set of word lines located in the middle of respective tiers to a target data state according to a first program scheme, applying a second number of program pulses that is greater than the first number to program nonvolatile memory cells of a second set of word lines located at or near boundaries of respective tiers to the target data state according to a second program scheme.

In one or more embodiments, the plurality of nonvolatile memory cells are located in a memory die and the means for selecting is located in a control die that is coupled to the memory die.

In one or more embodiments, the two or more tiers includes at least a first tier and a second tier that are physically connected along a joint and the second set of word lines includes at least a word line in the first tier that is nearest to the joint and a word line in the second tier that is nearest to the joint.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
one or more control circuits configured to connect to a plurality of nonvolatile memory cells in NAND strings that are coupled to word lines, wherein the one or more control circuits are configured to:
apply a first number of program pulses to program nonvolatile memory cells of a first set of word lines to a target data state according to a first program scheme, apply a second number of program pulses to program nonvolatile memory cells of a second set of word lines to the target data state according to a second program scheme, the second set of word lines includes one or more edge word line or joint word line and the second number of program pulses is greater than the first number of program pulses.

2. The apparatus of claim 1, wherein the first number is one and the second number is two or more.

3. The apparatus of claim 1, wherein the first number is more than one and the second number is more than the first number by at least two.

4. The apparatus of claim 1, wherein the NAND strings are formed in a lower tier and an upper tier that are joined along an interface, the second set of word lines consists of an edge word line at the bottom of the lower tier, a first joint word line at the top of the lower tier and a second joint word line at the bottom of the upper tier.

5. The apparatus of claim 4, wherein the first set of word lines consists of all word lines coupled to the NAND strings except the edge word line, the first joint word line and the second joint word line.

6. The apparatus of claim 1, wherein the NAND strings are formed in a lower tier, a middle tier and an upper tier, the lower tier is joined to the middle tier along a first interface and the upper tier joined to the middle tier along a second interface, the second set of word lines consists of an edge word line at the bottom of the lower tier, a first joint word line at the top of the lower tier, a second joint word line at the bottom of the middle tier, a third joint word line at the top of the middle tier and a fourth joint word line at the bottom of the upper tier.

7. The apparatus of claim 6, wherein the first set of word lines consists of all word lines coupled to the NAND strings except the edge word line and the first, second, third and fourth joint word lines.

8. The apparatus of claim 1, wherein the program pulses of the first program scheme have a first voltage, the program pulses of the second program scheme have a second voltage and the second voltage is less than the first voltage.

9. The apparatus of claim 1, wherein the first program scheme includes applying the first number of program pulses over a first time period and the second program scheme includes applying the second number of program pulses over a second time period that is longer than the first time period.

10. A method of programming a plurality of nonvolatile memory cells in a memory structure that includes NAND strings extending through two or more tiers with word lines of the two or more tiers coupled to the plurality of nonvolatile memory cells, comprising:
applying a first number of program pulses to a first set of word lines to program memory cells of the first set of word lines to a target data state according to a first program scheme;
identifying a second set of word lines according to their locations within the two or more tiers; and
applying a second number of program pulses that is greater than the first number to program memory cells of the second set of word lines to the target data state according to a second program scheme.

11. The method of claim 10, wherein applying the first number of program pulses consists of applying a single pulse and applying the second number of program pulses consists of applying two or more pulses.

12. The method of claim 10, wherein applying the first number of pulses consists of applying two or more pulses and applying the second number of pulses consists of applying more than the first number of pulses.

13. The method of claim 10, wherein identifying the second set of word lines includes identifying at least one edge word line at the bottom of a lowest tier of the two or more tiers.

14. The method of claim 13, wherein identifying the second set of word lines further includes identifying at least one joint word line at the top of the lowest tier of the two or more tiers.

15. The method of claim 14, wherein identifying the second set of word lines further includes identifying at least one joint word line at the bottom of a tier above the lowest tier of the two or more tiers.

16. The method of claim 10, wherein the program pulses of the first program scheme have a first voltage, the program pulses of the second program scheme have a second voltage and the second voltage is less than the first voltage.

17. The method of claim 16, wherein the program pulses of the first program scheme have a first pulse width, the program pulses of the second program scheme have a second pulse width and the second pulse width is less than the first pulse width.

18. A storage system comprising:
a plurality of nonvolatile memory cells arranged in NAND strings that extend through two or more tiers and connect to word lines in each tier; and
means for selecting a program scheme for a word line according to word line location in a respective tier of the two or more tiers, applying a first number of program pulses to program nonvolatile memory cells of a first set of word lines located in the middle of respective tiers to a target data state according to a first program scheme, applying a second number of program pulses that is greater than the first number to program nonvolatile memory cells of a second set of word lines located at or near boundaries of respective tiers to the target data state according to a second program scheme.

19. The storage system of claim 18, wherein the plurality of nonvolatile memory cells are located in a memory die and the means for selecting is located in a control die that is coupled to the memory die.

20. The storage system of claim 18, wherein the two or more tiers includes at least a first tier and a second tier that are physically connected along a joint and the second set of word lines includes at least a word line in the first tier that is nearest to the joint and a word line in the second tier that is nearest to the joint.
